(19) United States
(12) Patent Application Publication
(10) Pub. No.: US 2025/0359371 A1
(43) Pub. Date: Nov. 20, 2025

(54) METHOD FOR MANUFACTURING A PHOTONIC OR OPTOELECTRONIC DEVICE

(71) Applicant: STMicroelectronics International N.V., Geneva (CH)

(72) Inventors: Sylvie DEL MEDICO, Crolles (FR); Delia RISTOIU, St. Ismier (FR)

(73) Assignee: STMicroelectronics International N.V., Geneva (CH)

(21) Appl. No.: 19/201,210

(22) Filed: May 7, 2025

(30) Foreign Application Priority Data
May 17, 2024 (FR) FR2405065

(51) Int. Cl. H10F 39/00; H10F 39/18

(52) U.S. Cl. CPC H10F 39/805; H10F 39/024; H10F 39/184; H10F 39/806; H10F 39/811

(57) ABSTRACT

A method of manufacturing a photonic or optical device includes the following steps: a) providing a semiconductor substrate, having a first area and a second area, covered with a stack, where an upper portion of the stack covering the first area includes a dielectric layer having an interconnection element covered by a metal pad formed therein; b) forming a protection layer at least on the metal pad; c) forming a passivation element on the first and second areas; d) forming a first opening at the first area extending down to the protection layer in front of the metal pad; e) forming a second opening at the second area extending down to the substrate; and f) making the metal pad accessible by removing the protection layer in the first opening.

### PRIORITY CLAIM

This application claims the priority benefit of French Application for Patent No. FR2405065, filed on May 17, 2024, the content of which is hereby incorporated by reference in its entirety to the maximum extent allowable by law.

### TECHNICAL FIELD

The present disclosure generally concerns photonic or optoelectronic devices, such as image acquisition devices or image sensors, and their manufacturing method.

### BACKGROUND

A method of manufacturing photonic or optoelectronic devices comprises a plurality of phases.

In a first phase (referred to as a front end of line (FEOL) phase), components such as, among others, transistors, diodes, resistors, and/or capacitors, are formed inside and/or on top of a semiconductor substrate.

In a second phase (referred to as a back end of line (BEOL) phase), the components are interconnected by an electrical interconnection structure. An interconnection structure typically comprises conductive metal tracks (or lines), generally a plurality of metal tracks stacked on a plurality of levels and electrically insulated from one another by insulating layers. Vias cross one or a plurality of insulating layers of the interconnection structure to electrically couple the metal tracks to one another.

The end of the interconnection structure is the level most distant from the substrate. It may comprise at least one additional metal track and/or at least one metal pad to couple components of the integrated circuit to other locations of said integrated circuit or to couple the integrated circuit to another electronic circuit, for example a printed circuit.

The vias, the metal tracks, as well as the additional metal track may be made of copper.

In the case of optical devices and/or of photonic devices, the metal pad is often made of aluminum to be able to perform a wire bonding.

Such devices are also generally provided with a trench extending from the upper surface of the device to the substrate. The depth of the trench may range up to several tens of micrometers, particularly in the case of photonic devices.

Given the depth of the trench, it has to be formed at the end of the method.

The trench is, for example, formed according to the following steps: forming a resin mask, wherein openings of the mask are arranged in front of the position of the trench, with the resin mask covering the pad; etching of the trench; and removing the resin.

However, these steps may cause the contamination or the damaging of the aluminum pad since, on the one hand, a prolonged contact between the polymer material of the resin and the aluminum pad causes a contamination of the surface of the aluminum pad, and on the other hand, the removal of the resin may damage the surface of the pad.

There exists a need to obtain a method of manufacturing a photonic or optoelectronic device enabling to form deep trenches while preserving the metal pads of the device.

### SUMMARY

In an embodiment, a method of manufacturing a photonic or optical device comprises the following steps: a) providing a semiconductor substrate having a first area and a second area, the semiconductor substrate being covered with a stack, an upper portion of the stack covering the first area being a dielectric layer having an interconnection element formed therein, a metal pad being formed on the interconnection element; b) forming a protection layer at least on the first area to cover at least the metal pad; c) forming a passivation element on the first area and the second area, the passivation element comprising a bottom layer made of a material different from a material of the protection layer; d) forming a first opening in the passivation element above the metal pad, the first opening extending from an upper surface of the passivation element to the protection layer; e) forming a second opening at the level of the second area, the second opening extending from an upper surface of the passivation element to the semiconductor substrate; and f) removing the protection layer positioned in the first opening to make the metal pad accessible.

According to a specific embodiment, the metal pad is made of aluminum.

According to a specific embodiment, the protection layer is an alumina layer.

According to a specific embodiment, the protection layer is removed by wet etching.

According to a specific embodiment, the protection layer is a nitride layer.

According to a specific embodiment, an additional oxide layer is formed at least on the metal pad between step a) and step b).

According to a specific embodiment, the protection layer is removed by dry etching.

According to a specific embodiment, the bottom layer of the passivation element is made of oxide.

According to a specific embodiment, the passivation element further comprises (at least one) another oxide layer and/or a nitride layer.

According to a specific embodiment, the passivation element successively comprises a bottom layer of undoped silicate glass, an intermediate layer of phosphorus-doped silicon oxide, and a nitride top layer.

According to a specific embodiment, step d) is carried out by etching through a first resin layer exhibiting a through hole in front of the first opening to be formed.

According to a specific embodiment, step e) is carried out by etching through a second resin layer exhibiting a respective through hole in front of the second opening to be formed, the second resin layer filling the first opening and the method comprises, before step f), removing the resin filling the first opening.

In an embodiment, a photonic or optical device comprises: a support substrate having a first area and a second area, the semiconductor substrate being covered with a stack, an upper portion of the stack covering the first area being a dielectric layer having an interconnection element formed therein, a metal pad being formed on the interconnection element; a passivation element covering the stack above the first area and second area, the passivation element comprising a bottom layer; a protection layer being arranged between the stack and the passivation element, the bottom layer being made of a material different from a material of the protection layer; a first opening extending from an upper surface of the passivation element to an upper surface of the metal pad; and a second opening, extending from the upper surface of the passivation element to the semiconductor substrate, at the level of the second area.

According to a specific embodiment, the second opening penetrates in the semiconductor substrate down to a depth of at least 10 μm.

According to a specific embodiment, the protection layer is made of alumina.

According to a specific embodiment, the protection layer is made of nitride and wherein an additional oxide layer is arranged under the protection layer.

According to a specific embodiment, a portion of the stack covering the second area is a waveguide.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIGS. 1 to 10 schematically show different steps of a method of manufacturing a photonic or optoelectronic device;

FIG. 11 schematically shows a side view and a cross-section view a photonic or optoelectronic device; and

FIG. 12 schematically shows a side view and a cross-section view a photonic device.

### DETAILED DESCRIPTION

In the different drawings, the different elements are not shown at a uniform scale to make the drawings more readable.

Like features have been designated by like references in the various figures. In particular, the structural and/or functional features that are common among the various embodiments may have the same references and may dispose identical structural, dimensional and material properties.

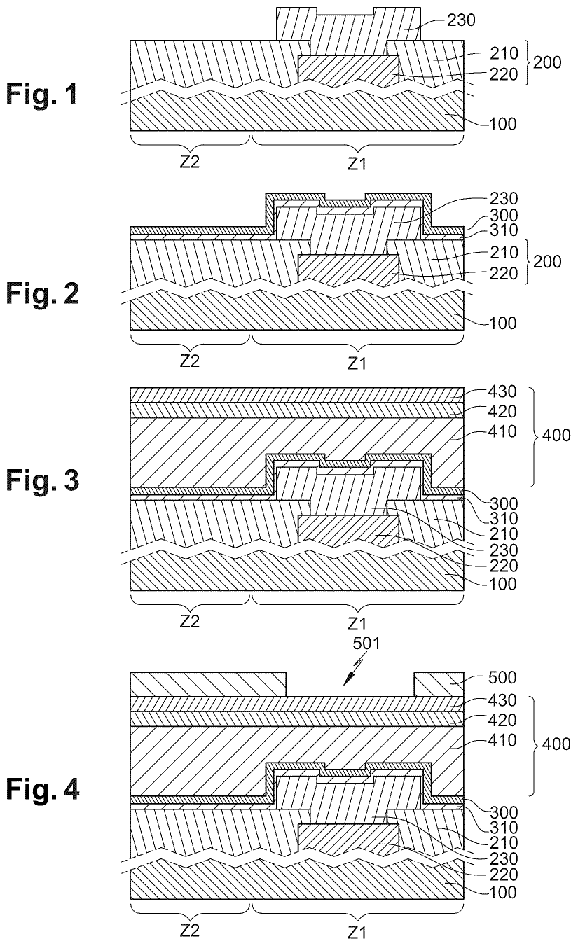

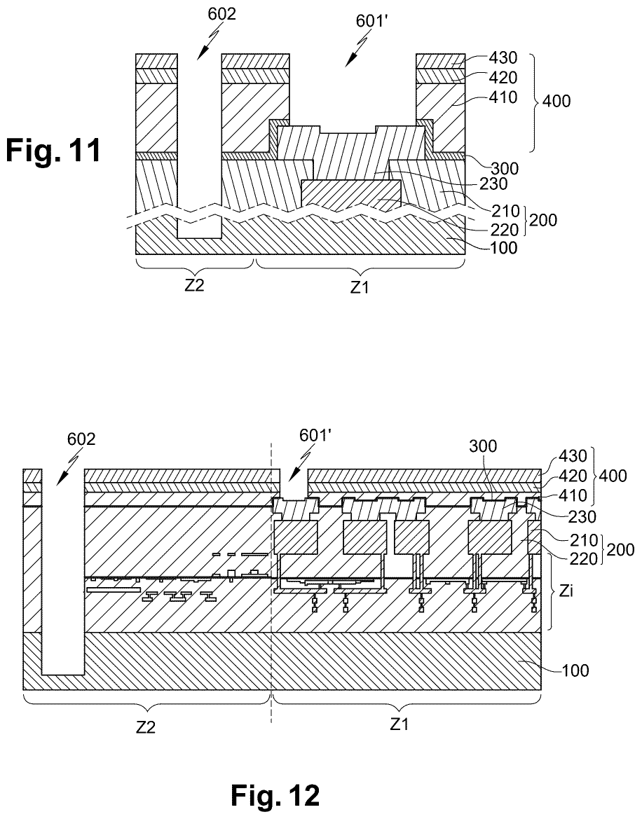

For clarity, only those steps and elements which are useful to the understanding of the described embodiments have been shown and are described in detail. In particular, FIGS. 1 to 11 show the semiconductor substrate and the upper level (or end) of the interconnection structure, that is, the level most distant from the substrate. Further, these drawings only show in this upper level an insulating layer in which is formed an interconnection element covered with a conductive pad. However, this upper level may comprise a plurality of interconnection elements (vias and/or pads), a plurality of conductive tracks and/or of other insulating layers. The interconnection structure further generally comprises at least another level under the upper level in which are arranged, in particular, other interconnection elements. Between the upper level and the substrate, the device comprises an intermediate level. As an illustration, this intermediate level (noted ‘Zi’) is shown in FIG. 12. In FIGS. 1 to 11, the upper portion of the interconnection structure and the substrate are shown, but not the intermediate level to make the drawings more readable.

The vias and the pads of the interconnection structure may be generally designated as “interconnection element”, which interconnection elements may also comprise conductive tracks.

Also, for clarity, the electronic components formed inside or on top of the substrate are not shown.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

For clarity, the expressions “different materials”, “chemically different materials”, and so on, referring to two materials means that the two materials differ in terms of the elements present, their proportions, and/or the way atoms are arranged in their structures. For example, they may have either a different chemical nature (e.g., one oxide and one nitride) or they belong to the same class of material (e.g., both oxide materials) but they comprise at least one structural element (i.e., an element with a stochiometric percentage of at least 20%) different from each other. For example, aluminum oxide (Al₂O₃) and silicon oxide (SiO₂) are considered two different materials.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

When reference is made to an upper layer, level, or surface, it is referred to the layer, the level, or the surface most distant from the substrate, as compared with another layer, level, surface closer to the substrate.

Unless specified otherwise, the expressions “about”, “approximately”, “substantially”, and “in the order of” signify plus or minus 10%, preferably of plus or minus 5%.

Unless specified otherwise, by in the range of values from X to Y, there is meant that terminal values X and Y are included in the range.

In the rest of the disclosure, a layer or a film is called transparent to a radiation when the transmittance of the radiation through the layer or the film is greater than 50%, and preferably greater than 70%.

The device may be a photonic device. It may also be an optoelectronic device.

There will now be described in further detail a method of manufacturing a photonic or optoelectronic device in relation with FIGS. 1 to 11.

The method comprises the following steps:

a) providing a base structure comprising a semiconductor substrate 100, having a first area Z1 and a second area Z2, the substrate being covered with a stack, an upper portion of the stack covering first area Z1 being a dielectric layer 210 having an interconnection element 220 formed therein, a metal pad 230 being formed on interconnection element 220 (FIG. 1);

b) forming a protection layer 300 at least on the metal pad 230 (FIG. 2);

c) forming a passivation element 400 covering first area Z1 and second area Z2 (FIG. 3);

d) forming a first opening 601 in passivation element 400 above metal pad 230, the first opening 601 extending from an upper surface of passivation element 400 to the protection layer 300 (FIGS. 4 to 6);

e) forming a second opening 602 in passivation element 400 at the level of second area Z2, the second opening 602 extending from an upper surface of passivation element 400 to penetrate into substrate 100 (FIGS. 7 to 9); and

f) removing the protection layer 300 positioned in first opening 601 to make metal pad 230 accessible (FIG. 10).

The base structure provided at step a) (only a portion of which is shown in FIGS. 1 to 11) comprises a semiconductor substrate 100 covered by a stack.

Substrate 100 is made of a semiconductor material. Preferably, it is made of silicon. The substrate has, for example, a thickness in the range from 775 μm to 850 μm.

Substrate 100 is covered with a stack comprising different layers and different elements.

The stack may have a thickness in the range from 10 to 20 μm.

A first portion of the stack is positioned above first area Z1 and a second portion of the stack is positioned above second area Z2.

The first portion of the stack and the second portion of the stack are adjacent. Each portion may have a specific function.

For example, in the case of a photonic device, the first portion may comprise components covered with an interconnection structure and the second portion of the stack may be, for example, a waveguide.

The components are, for example, transistors, diodes, resistors, and/or capacitors, formed inside and/or on top of substrate 100.

The interconnection structure comprises insulating layers crossed by lines and/or vias and/or metal pads. The lines, the vias, and the pads extend depth-wise in the insulating layers.

The lines, the vias, and the pads are, for example, made of copper. The insulating layers are, for example, made of silicon dioxide (SiO₂). The copper elements may be formed by a method referred to as the “Damascene” process which is well-known by those skilled in the art.

More particularly, upper interconnection layer 200 comprises an insulating layer 210 having an interconnection element 220 formed therein. Interconnection element 220 is an electrically conductive element. It is, preferably, made of copper. It may be a pad.

In the drawings, interconnection element 220 is exemplarily shown as being recessed with respect to the upper surface of the insulating layer 210 of the interconnection structure.

Interconnection element 220 is covered with a metal pad 230. Conductive pad 230 is, preferably, made of aluminum. It is, for example, formed by Plasma Vapor Deposition (PVD).

During step b), a protection layer 300 is formed (FIG. 2). It is a layer intended to protect pad 230, particularly during the forming of second opening 602. Conductive pad 230 will not be in contact with the resin, nor with the products necessary for the removal of the resin.

Protection layer 300 is deposited at least on the upper surface of the metal pad 230. Preferably it may be deposited at least on first area Z1. It may be deposited on first area Z1 and on second area Z2. It may be deposited over the entire plate.

Protection layer 300 may be formed by an atomic layer deposition (ALD) technique or by a chemical vapor deposition (CVD) technique, for example a plasma-enhanced chemical vapor deposition (PECVD) technique.

Protection layer 300 may be made of a material selected from among nitrides, carbides, carbonitrides, and oxides (or combinations thereof). In particular, the material is selected from among silicon nitrides, silicon carbides, silicon carbonitrides, and aluminum oxides (also called alumina).

In one embodiment not explicitly shown, the protection layer 300 may be integrated in a protection multi-layer (e.g., a bilayer). The materials forming each sub-layer could be selected from among the previously mentioned materials. The protection multi-layer is, for example, a silicon nitride/alumina bilayer.

According to a first embodiment (FIGS. 1-10), the protection layer 300 is preferably made of silicon nitride.

Protection layer 300 has a thickness in the range from 10 to 80 nm, preferably from 30 to 80 nm, more preferably from 40 to 60 nm.

An additional oxide layer 310 may be arranged under protection layer 300. In other words, additional layer 310 is positioned between, on the one hand, protection layer 300 and, on the other hand, pad 230 and upper interconnection layer 200. The additional layer 310 may have the purpose of simplifying the deposition of the protection layer 300.

Additional layer 310 is, for example, made of silicon oxide.

Additional layer 310 has, for example, a thickness in the range from 10 to 30 nm, for example 20 nm.

Such an additional layer 310 is, for example, shown in FIGS. 1 to 10.

According to a second alternative embodiment, as shown in FIGS. 11 and 12, protection layer 300 may be directly in contact with pad 230 and upper interconnection layer 200. In this second embodiment, there is no intermediate layer (like layer 310) between these elements and protection layer 300. The protection layer 300 may be a layer of oxide, especially of alumina.

The alumina protection layer 300 has, for example, a thickness in the range from 20 to 40 nm, for example 30 nm.

The alumina protection layer 300 may be formed by an Atomic Layer Deposition (ALD) process.

During step c), a passivation element 400 is formed (FIG. 3).

Passivation element 400 may be a monolayer or a stack of a plurality of layers (multilayer), in particular a bilayer or a trilayer. Passivation element 400 comprises at least one substantially moisture-tight layer enabling to protect the underlying elements from moisture. It is, in particular, a nitride layer. More preferably still, it comprises a nitride layer 430 arranged on one or a plurality of (preferably two) oxide layers 410, 420.

Oxide layers 410, 420 are, in particular, preferably made of a material selected from among undoped silicate glass (USG) or phosphorus silicate glass (PSG).

Passivation element 400 comprises, for example, successively from protection layer 300: a first oxide layer 410 (bottom layer), preferably made of USG, a second oxide layer 420 (intermediate layer), preferably made of PSG, a nitride layer 430 (top layer), preferably made of silicon nitride.

The thickness of oxide layers 410, 420 may be in the range from 500 to 2000 nm, preferably in the range from 1000 to 1800 nm, for example equal to 1500 nm.

First oxide layer 410 and second oxide layer 420 form a bilayer having a thickness in the range from 500 nm to 2 μm.

The thickness of nitride layer 430 may be in the range from approximately 300 to 700 nm, for example equal to approximately 500 nm.

Passivation element 400 is configured to protect certain elements of the device, and in particular the interconnection structure.

The different layers of the passivation element 400 may be formed by a Chemical Vapor Deposition (CVD), particularly by a plasma-enhanced CVD (PECVD), process.

During step d), a first opening 601 is formed in first area Z1, above pad 230. Opening 601 extends from an upper surface of passivation element 400 to the protection layer 300. Opening may extend to the upper surface of protection layer 300 or may stop within the thickness of the protection layer 300. In particular, first opening 601 may be formed by photolithography.

In order to perform a selective etching, the material of the protection layer 300 is (chemically) different from the material of the bottom layer 410 of the passivation element 400 (i.e., the layer of the passivation element closer to the protection layer 300 along the vertical direction). Preferably, the bottom layer 410 is in contact with the protection layer 300.

In the case of the protection multi-layer, the material of at least the protection layer 300 is (chemically) different from the material of the bottom layer 410, while the other sub-layer of the protection multi-layer could be made of any material within those described above.

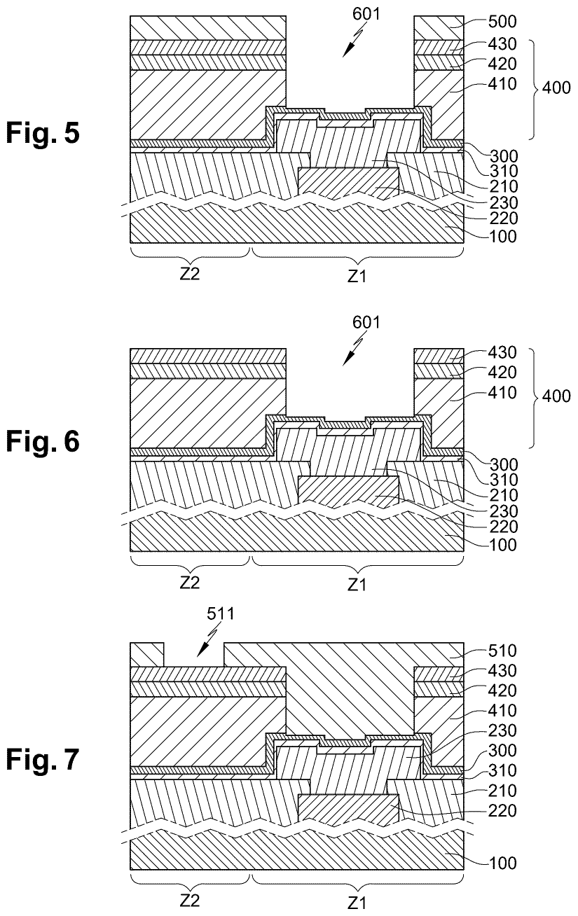

First opening 601 is, for example, formed according to the following steps: forming a resin layer 500 on passivation element 400, the resin layer comprising at least one through hole 501 arranged in front of pad 230 (FIG. 4), etching passivation element 400 through the pattern (FIG. 5), removing resin 500 (FIG. 6).

FIG. 6 illustrates the structure obtained at the end of a photolithography step performed on the upper surface of passivation element 400.

The pattern can be obtained by conventional photolithography steps, that is: the deposition of a resist layer 500; the exposure of resist layer 500 to a radiation through a mask formed of opaque and transparent areas defined to obtain in the resist a desired pattern; and the dissolving in a specific aqueous or organic solution, called development solution, of a portion of the resist layer to develop the pattern and form a through opening 501 above pad 230.

The shown pattern is, for example, obtained by using a positive resist. The portion of the resist exposed to the radiation (through the transparent areas of the mask) becomes soluble in the development solution, and the portion of the resist which is not exposed (through the opaque areas of the mask) remains non-soluble in the development solution. Alternatively, the resist may be negative. The portion of the resist exposed to the radiation then becomes non-soluble in the development solution and the portion of the resist which is not exposed remains soluble in the development solution.

The etching of passivation element 400 is performed through the resist pattern forming an etch mask, so that the etching occurs in the openings 501 of the pattern and in the areas which are not covered by said pattern.

The etching forms a cavity 601 (first opening) above pad 230 in passivation element 400. Protection layer 300 may not be etched or may not be substantially etched when opening cavity 601. In this case the bottom of the cavity 601 is (substantially) located at the upper surface of the protection layer 300. Alternatively, protection layer 300 may be partially etched, for example due to a partial over-etching during the etching step. In this case the bottom of the cavity 601 is in the thickness of the protection layer 300.

The etching may be a dry etching, for example implementing a fluorine-based plasma, or a wet etching, particularly by means of a solution of fluorinated acid, for example hydrofluoric acid.

The acid concentration in the solution and/or the etching time may be adjusted to etch down to a given depth.

Then, a step of removal of resist layer 500 is carried out, for example by dry etching, particularly by implementing an oxygen-based plasma.

First opening 601 forms a cavity. The width of cavity made by opening 601 is defined by the width of opening 501 in the resist pattern. The height of cavity made by opening 601 is defined by the etch depth.

For example, first opening 601 has a circular cross-section. The diameter of the cross-section may be in the range from 40 to 50 μm. The height of the cavity depends on the thickness of passivation element 400.

At the end of step d), protection layer 300 is still present. It then plays the role of an etch stop layer.

During step e), a second opening 602 is formed at the level of second area Z2.

Second opening 602 is a deep trench. By deep, there is meant a depth of at least 10 μm. The second opening has, for example, a depth in the range from 10 to 100 μm. Second opening 602 extends at least down to the upper surface of substrate 100 and, preferably, extends into substrate 100. A portion of substrate 100 is etched. Substrate 100 may be etched down to a depth from 5 to 60 μm.

Second opening 602 has, for example, a cross-section area greater than 1 mm².

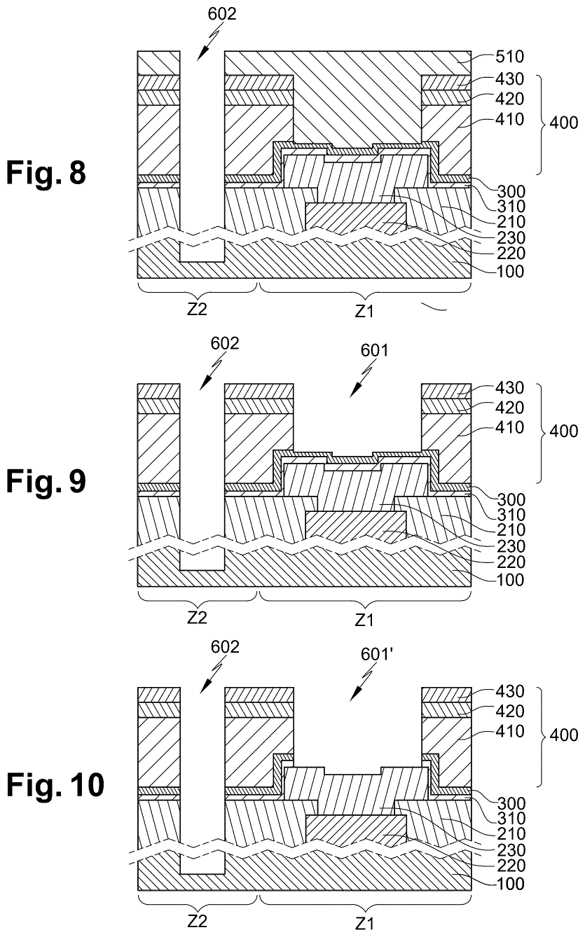

Second opening 602 is, for example, formed according to the following steps: forming a resin layer 510 on passivation element 400, resin layer 510 having a through hole 511 positioned above second area Z2, resin layer 510 filling first opening 601 (FIG. 7); forming a second opening 602 in the device, second opening 602 being formed by etching from the upper surface of passivation element 400, second opening 602 extending into substrate 100 (FIG. 8); and removing resin layer 510 (FIG. 9).

The etching may be a dry etching, for example implementing a fluorine-based plasma, or a wet etching, particularly by means of a solution of fluorinated acid, for example hydrofluoric acid.

The acid concentration in the solution and/or the etching time may be adjusted to etch down to a given depth.

Protection layer 300 forms an intermediate layer between conductive pad 230 and resin 510 but also between pads 230 and the products necessary for the removal of the resin. Protection layer 300 forms a diffusion barrier layer.

During step f), protection layer 300 (and, in case, any further sub-layer of the protection multi-layer), and possibly additional layer 310, are removed to make pad 230 accessible.

When protection layer 300 comprises a nitride layer, the etching is, for example, a plasma etching.

When protection layer 300 is an alumina layer, the etching is, for example, a wet etching.

At the end of the method, there is obtained a device having, in the first area, a further cavity 601′ at the bottom of which metal pad 230 is accessible, and, in the second area, a deep trench 602 (FIGS. 10 to 12). The surface of pad 230 is neither contaminated, nor deteriorated. The volume of cavity 601′ corresponds to the global volume including the volume of cavity 601 and the volume previously occupied by protection layer 300 (and, in case, any further sub-layer of the protection multi-layer), and possibly by the additional oxide layer 310.

FIG. 12 shows, as an illustration and without for this to be limiting, a photonic device obtained with such as method.

In the first area, there is at least one cavity 601′. A pad 230 is arranged in cavity 601′. It may be used to connect the device to an outer element.

In second area Z2, a deep trench 602 is formed. It extends from the upper surface of passivation element 400 into substrate 100. It crosses the entire thickness of the first portion of the stack. Deep trench 602 may be used for a laser, for example.

The nitride layer 430 forming the upper layer of passivation element 400 may be structured to give way to light.

The use of a protection layer 300 formed of an alumina monolayer is particularly advantageous since it is transparent. It may be used even for waveguides based on nitride.

The optical device may be used as an image acquisition device operating in near infrared (NIR), that is, for an electromagnetic radiation having a wavelength in the range from 800 nm to 2,500 nm, and more particularly, in short-wave infrared (SWIR), that is, for an electromagnetic radiation having a wavelength in the range from 800 nm to 2,000 nm, preferably from 900 nm to 1,700 nm, typically 1.4 μm.

The device may also be used in the implementation of 5G networks, of datacenters, and of servers.

The device is, for example, intended to be used in communication equipment, or in computers and peripherals.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A method of manufacturing a photonic or optical device, comprising the following steps:
a) providing a semiconductor substrate having a first area and a second area, wherein the semiconductor substrate is covered with a stack, an upper portion of the stack covering the first area being a dielectric layer having an interconnection element formed therein, and including a metal pad formed on the interconnection element;
b) forming a protection layer at least on the first area to cover at least the metal pad;
c) forming a passivation element on the first area and the second area, the passivation element comprising a bottom layer made of a material different from a material of the protection layer;
d) forming a first opening at the first area in the passivation element above the metal pad, the first opening extending from an upper surface of the passivation element to the protection layer;
e) forming a second opening at the second area, the second opening extending from an upper surface of the passivation element to the semiconductor substrate; and
f) removing the protection layer positioned in the first opening to make the metal pad accessible.

2. The method according to claim 1, wherein the metal pad is made of aluminum.

3. The method according to claim 1, wherein the protection layer is an alumina layer.

4. The method according to claim 2, wherein step f) removing the protection layer comprises performing a wet etching.

5. The method according to claim 1, wherein the protection layer is a nitride layer.

6. The method according to claim 5, further comprising forming an additional oxide layer at least on the metal pad between step a) and step b).

7. The method according to claim 5, wherein step f) removing the protection layer comprises performing a dry etching.

8. The method according to claim 1, wherein the bottom layer of the passivation element is made of oxide, and wherein the passivation element further comprises another oxide layer and/or a nitride layer.

9. The method according to claim 1, wherein the passivation element is a stack of layers successively comprising: a bottom layer made of undoped silicate glass, an intermediate layer made of phosphorus-doped silicon oxide, and a top layer made of a nitride.

10. The method according to claim 1, wherein step d) forming the first opening comprises etching through a first resin layer exhibiting a through hole in front of a location where the first opening is to be formed.

11. The method according to claim 10, wherein step e) forming the second opening comprises etching through a second resin layer exhibiting a respective through hole in front of a location where the second opening is to be formed.

12. The method according to claim 10, where the second resin layer fills the first opening, and wherein the method further comprises, before step f), removing the resin filling the first opening.

13. A photonic or optical device, comprising:
a semiconductor substrate having a first area and a second area;
a stack covering the semiconductor substrate, wherein an upper portion of the stack covers the first area and comprises a dielectric layer having an interconnection element formed therein, and a metal pad formed on the interconnection element;
a passivation element covering the stack above the first area and the second area, wherein the passivation element comprises a bottom layer;
a protection layer arranged between the stack and the passivation element;
wherein the bottom layer is made of a material different from a material of the protection layer;
a first opening at the first area extending from an upper surface of the passivation element to an upper surface of the metal pad; and
a second opening at the second area extending from the upper surface of the passivation element to the semiconductor substrate.

14. The device according to claim 13, wherein the second opening penetrates in the semiconductor substrate down to a depth of at least 10 μm.

15. The device according to claim 13, wherein the protection layer is made of alumina.

16. The device according to claim 13, wherein the protection layer is made of nitride and further comprising an additional oxide layer arranged under the protection layer.

17. The device according to claim 13, wherein a portion of the stack covering the second area is a waveguide.
